(19) United States
(12) Patent Application Publication
(10) Pub. No.: US 2025/0336744 A1
(43) Pub. Date: Oct. 30, 2025

(54) SEMICONDUCTOR DEVICES WITH OXIDIZED LAYER SEGMENTS IN DEVICE REGIONS

(71) Applicant: TEXAS INSTRUMENTS INCORPORATED, Dallas, TX (US)

(72) Inventors: Jackson Bauer, Rowlett, TX (US); Bhaskar Srinivasan, Allen, TX (US); Brian Goodlin, Plano, TX (US); Chang Soo Suh, Allen, TX (US)

(21) Appl. No.: 18/650,299

(22) Filed: Apr. 30, 2024

(51) Int. Cl. H01L 23/31; H01L 21/02; H01L 29/20; H01L 29/66; H01L 29/778

(52) U.S. Cl. CPC H01L 23/3171; H01L 21/02241; H01L 21/02252; H01L 23/3192; H10D 30/015; H10D 30/475; H10D 62/8503

(57) ABSTRACT

Semiconductor devices with oxidized layer segments in a barrier layer are described. In some examples, a semiconductor device includes a semiconductor substrate, a channel layer over the semiconductor substrate, and a barrier layer over the channel layer. The semiconductor device further includes an oxidized layer including a first segment formed only in a portion of a drain access region of the semiconductor device.

### FIELD OF THE DISCLOSURE

Disclosed implementations relate generally to the field of semiconductor devices and their fabrication. More particularly, but not exclusively, the disclosed implementations relate to III-N semiconductor devices including oxidized layer segments in select device regions.

### BACKGROUND

Group III nitride materials (also referred to as III-N materials) possess a unique combination of physical and electrical properties found to be beneficial in modern microelectronics and optoelectronics. Among these properties are wide bandgap, high saturated drift rate, high breakdown voltage, high thermal conductivity, robust chemical and thermal stability, etc. Due to these characteristics, III-N materials are being considered as promising materials for fabrication of powerful high-frequency transistor structures capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to III-N semiconductor devices including oxidized layer segments in select device regions for increasing carrier density and/or mobility in a channel formed in a heterojunction structure. In one example, a semiconductor device is disclosed, which comprises, among others, a semiconductor substrate including a source region, a gate region, a drain region, and a drain access region between the gate region and the drain region; a channel layer over the semiconductor substrate; a barrier layer over the channel layer; a gate stack including a p-doped III-N (p-III-N) layer over the barrier layer in the gate region; and an oxidized layer including a first segment in at least a portion of the drain access region.

In one example, a semiconductor device is disclosed, which comprises, among others, a semiconductor substrate including a source region, a gate region, a drain region, and a drain access region between the gate region and the drain region; a channel layer over the semiconductor substrate; a barrier layer over the channel layer; and an oxidized layer including a first segment only in a portion of the drain access region.

In one example, a method fabricating a semiconductor device including oxidized layer segments in select device regions is disclosed. The method comprises, among others, forming a channel layer over a semiconductor substrate including a source region, a gate region, a drain region, and a drain access region between the gate region and the drain region; forming a barrier layer over the channel layer; forming a gate stack including a p-doped III-N (p-III-N) layer over the barrier layer in the gate region of the semiconductor substrate; and forming an oxidized layer including a first segment in at least a portion of the drain access region of the semiconductor substrate.

In one example, a method fabricating a semiconductor device having oxidized layer segments in select device regions is disclosed. The method comprises, among others, forming a channel layer over a semiconductor substrate including a source region, a gate region, a drain region, and a drain access region between the gate region and the drain region; forming a barrier layer over the channel layer; and forming an oxidized layer including a first segment only in a portion of the drain access region of the semiconductor substrate.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIGS. 1A-1D depict cross-sectional views of a semiconductor device including an EMODE GaN device at various stages of a process flow, where an oxidized layer may be provided in or over a barrier layer in select regions of the device according to some examples of the present disclosure;

FIGS. 2A-2E depict cross-sectional views of a semiconductor device including an EMODE GaN device at various stages of a process flow, where an oxidized layer may be provided in or over a barrier layer only in a portion of a drain access region of the GaN device according to some examples of the present disclosure;

FIGS. 3A-3H depict cross-sectional views of a semiconductor device including a DMODE GaN device at various stages of a process flow, where an oxidized layer may be provided in or over a barrier layer only in select regions of the GaN device according to some examples of the present disclosure;

FIGS. 4A-4H depict cross-sectional views of a semiconductor device including a DMODE GaN device at various stages of a process flow, where an oxidized layer may be provided in or over a barrier layer only in a portion of a drain access region of the GaN device according to some examples of the present disclosure; and

FIGS. 5 and 6 are flowcharts of methods of fabricating a semiconductor device including a GaN device having a segmented oxidized layer in a barrier layer according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of semiconductor devices based on Group III nitride materials, also referred to as III-N materials, such as gallium nitride (GaN) devices.

GaN devices, e.g., GaN transistors, provide certain performance advantages over silicon, including lower on-state resistance (e.g., drain-source resistance or RDSON), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a lateral 2-dimensional electron gas (2DEG) channel formed within the AlGaN/GaN hetero epitaxy structure that is used for device operation. Depletion mode (DMODE) GaN transistors are normally on, whereas enhancement mode (EMODE) GaN transistors are normally off. In some examples, an EMODE GaN transistors include a gate stack with a p-type doped gallium nitride (p-GaN) layer that depletes the 2DEG channel beneath the gate at zero or negative gate bias. Applying a positive gate voltage enhances the 2DEG channel and turns the EMODE GaN device on to allow current flow between the source and drain.

The density of carriers, e.g., electrons, in the 2DEG channel and their mobility is controlled by a variety of factors, including the concentration of Al in AlGaN, the stress in the films, and the thickness of the layers, among others. Whereas the carrier density in the 2DEG channel generally increases with higher Al content as well as higher film thicknesses, there may be physical limitations to the amount of Al that can be increased (e.g., higher Al content leads to higher stress and lower film quality). Further, there may be manufacturing limitations to forming layers of higher thicknesses, e.g., requiring longer growth phases, thus increasing cycle times and concomitant costs. On the other hand, higher 2DEG densities are desired as the higher density of carriers allows for lower on-resistance and maximum on current (Imax). Additionally, as carrier mobility is also related to device performance, higher electron mobility in the 2DEG channel is likewise desirable.

Examples of the present disclosure recognize the foregoing challenges and provide solutions for advantageously increasing the 2DEG electron density, mobility, and/or both, in various types of GaN device modes. In versions of some examples herein, an oxidized layer (e.g., an oxidized interface layer) is provided only in portions of a barrier layer in different device regions of a GaN device, which as will be seen below, may enhance various electrical parameters of the devices such as decreased sheet resistance of the 2DEG channel. Whereas the examples may provide various structures, materials and processes that may engender beneficial effects in a variety of device modes, no particular result is a requirement unless explicitly recited in a particular claim.

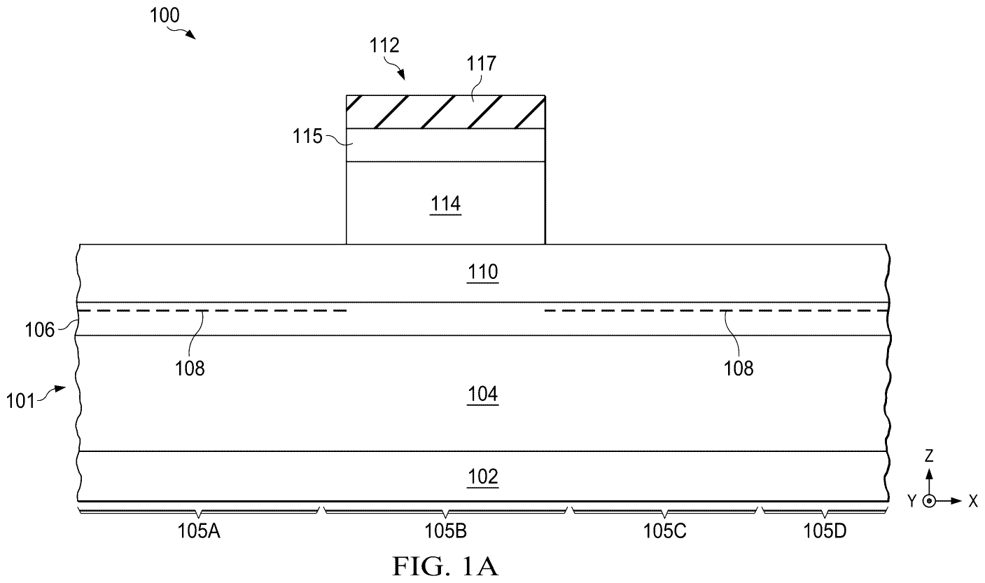

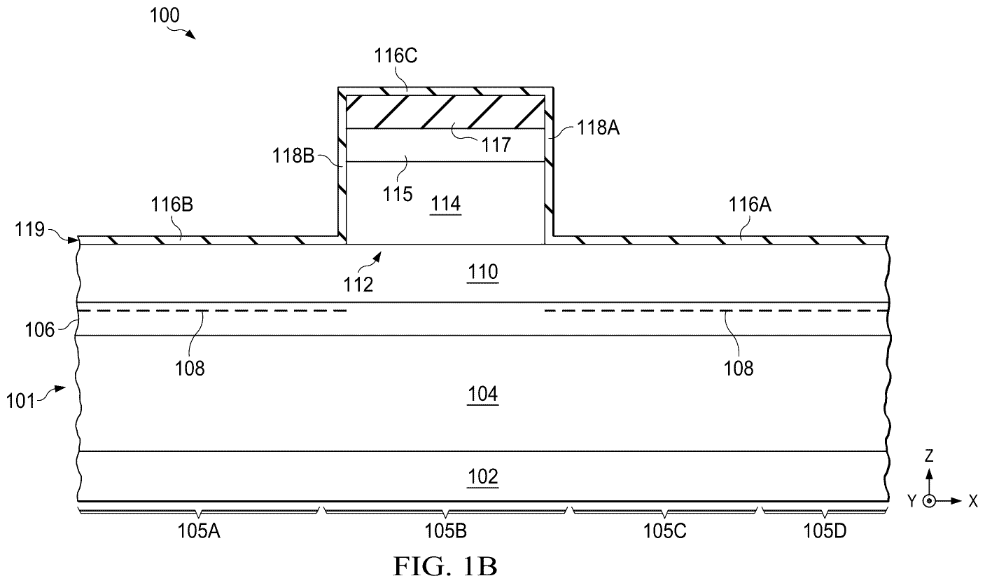

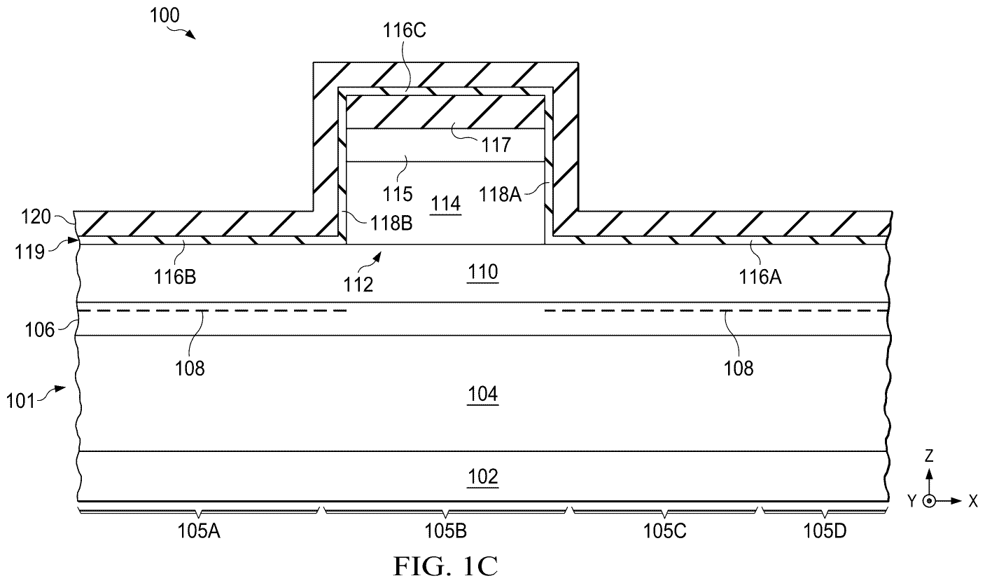

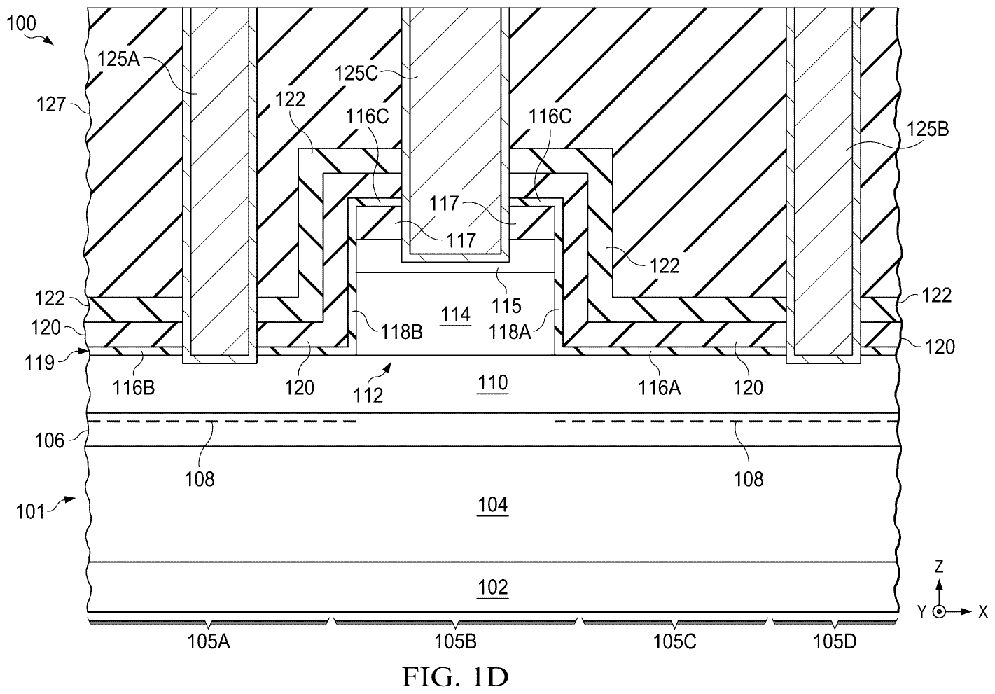

Referring to the drawings, FIGS. 1A-1D depict cross-sectional views of a semiconductor device 100 including an EMODE GaN device 101 at various stages of a process flow, where an oxidized interface layer may be provided in or over a barrier layer in select regions of the GaN device 101 according to some examples of the present disclosure. FIG. 1A depicts an intermediate stage of the semiconductor device 100 formed on a portion of a semiconductor substrate 102, which may be provided as a silicon wafer, a silicon-on-sapphire wafer, or a silicon carbide wafer, etc. A buffer layer 104 comprising one or more layers of III-N semiconductor material is formed on the substrate 102. In some examples where the substrate 102 is implemented as a silicon wafer or a sapphire wafer, the buffer layer 104 may include a nucleation layer having a stoichiometry that includes aluminum to match a lattice constant of the substrate 102. In versions of some examples, the buffer layer 104 may further include layers/sublayers of aluminum gallium nitride (AlGaN) with decreasing aluminum content, including an unintentionally doped (UID) GaN sublayer in some arrangements. For purposes of the examples herein, the various layers/sublayers of the buffer layer 104 are not specifically shown in the drawing Figures of the present disclosure.

Depending on implementation, the buffer layer 104 may have a thickness of about 1 micron (μm) to several microns, e.g., 3.5 μm to 5.0 μm, which may be formed by a suitable epitaxial process, e.g., a metal organic vapor phase epitaxy (MOVPE) process with several operations to form the various layers and/or sublayers. Depending on the sizing of the GaN device 101, the buffer layer 104 is formed to overlap an area of the substrate 102, where different regions such as a source region 105A, a gate region 105B, a drain region 105D and a drain access region 105C between the gate region 105B and the drain region 105D and may be provided with respect to the GaN device 101. A channel layer 106 operable to support a 2DEG channel 108 is formed on or over the buffer layer 104, which may be formed by a suitable MOVPE process using a gallium-containing gas reagent/source and a nitrogen-containing gas reagent/source. Although the channel layer 106 may primarily include GaN material, there may be optional trace amounts of other group III elements, such as aluminum or indium, in some implementations. Further, the channel layer 106 may be formed as a last portion of the buffer layer 104 in some additional and/or alternative arrangements.

Continuing to refer to FIG. 1A, a barrier layer 110 comprising III-N semiconductor material is formed over the channel layer 106 (or on the optional high bandgap sublayer, if present). In an example arrangement, the barrier layer 110 may have a thickness in a range from 1 nanometer (nm) to 60 nm, and may include aluminum and nitrogen. In some versions of this example, the barrier layer 110 may include gallium at a lower atomic percent than aluminum. In some versions, the barrier layer 110 may also include indium.

The barrier layer 110 over the channel/buffer stack 104/106 is operable as a heterojunction structure for causing the formation of a 2DEG channel 108 proximate to an interface between the barrier layer 110 and the channel layer 106. Whereas the stoichiometry and thickness of the barrier layer 110 may be configured to provide a suitable free charge carrier density (e.g., 3×10¹² cm⁻² to 2×10¹³ cm⁻²), the examples herein may be configured to increase the carrier density for a given heterojunction structure by providing a segmented oxidized layer in or over the barrier layer 110 in select regions of the GaN device 101 as will be set forth below.

For purposes of effectuating EMODE functionality, a gate stack 112 including a p-doped III-N (p-III-N) layer comprising one or more layers of III-N material is formed over the barrier layer 110 in the gate region 105B as shown in FIG. 1A. In versions of this example, a stack of layers comprising a p-doped GaN layer 114 (e.g., doped with magnesium (Mg) or other p-type dopants), an AlGaN cap layer 115 (e.g., devoid of p-doping) and a silicon nitride (SiN) cap layer 117 may be formed and patterned—e.g., using a gate stack mask and appropriate photolithography and etch process. In some examples, the p-doped GaN layer 114 may include a peak p-dopant concentration of about 1×10²⁰ atoms/cm³, and may have a thickness of about 50 nm to 200 nm. In some examples, the SiN cap layer 117 may be formed using a low-pressure chemical vapor deposition (LPCVD) process.

The formation of the gate stack 112 including the p-GaN layer 114 causes the 2DEG channel 108 to be reduced (e.g., absent in some cases) in the gate region 105B as shown in FIGS. 1A-1D. In versions of the examples herein, the source region 105A (where a source terminal or contact is be formed) and the drain region 105D (where a drain terminal or contact is to be formed) are asymmetrically disposed relative to the gate region 105B although it is not a requirement. For example, there may be a greater lateral distance between the gate region 105B and the drain region 105D than a lateral distance between the gate region 105B and the source region 105A by virtue of an access region, e.g., drain access region 105C, disposed between the gate region 105B and the drain region 105D. In some additional and/or alternative arrangements, a source access region may be provided between the source region 105A and the gate region 105B in a similar manner while still having source/drain region asymmetry with respect to the gate region 105B.

Additional details regarding the formation of EMODE GaN devices as well as DMODE GaN devices (which will be set forth further below for purposes of some examples of the present disclosure) may be found in the following U.S. Patent Applications: (i) U.S. Patent Application Publication No. 2022/0130988; (ii) U.S. Patent Application Publication No. 2022/0173234; and (iii) U.S. Patent Application Publication No. 2023/0094094; each of which is incorporated by reference herein in its entirety for all purposes, which may be individually and/or collectively referred to as “incorporated disclosures.”

FIG. 1B depicts a stage where an oxidized layer 119 (e.g., oxidized interface layer) is formed in or over the barrier layer 110 in select regions of the GaN device 101 of the semiconductor device 100 according to some examples herein. In one implementation, the oxidized layer 119, also referred to as a segmented oxidized layer in some examples, is formed by a plasma treatment involving nitrous oxide (N₂O) in a plasma-enhanced CVD (PECVD) tool. Depending on configuration, nitrous oxide may be supplied to the reactor chamber at a flow rate of about 1.5 standard liters per minute (slm) to 2.5 slm for about 60 to 90 seconds, with RF power greater than 600 W and having a frequency range of about 10 MHz to 20 MHz. Further, a chamber pressure of about 300 Pa to 400 Pa and a temperature of about 350° C. to 450° C. may be maintained during the treatment process in some arrangements. In the example of FIG. 1B, the plasma treatment is applied to all the regions of the GaN device 101, i.e., the source region 105A, the gate region 105B (which is overlain by the gate stack 112), the drain access region 105C and the drain region 105D. Accordingly, the entire barrier layer 110 except a portion underlying the gate stack 112 corresponding to the gate region 105B is exposed to the reactive plasma species. As will be set forth further below, a pre-plasma treatment passivation layer, where provided, may be patterned to selectively open and thus expose different regions in the barrier layer 110 of the GaN device 101 to the plasma treatment in order to form a segmented oxidized layer for purposes of some additional and/or alternative examples herein.

Continuing to refer to the example of FIG. 1B, the oxidized layer 119 includes a lateral or horizontal segment 116A extending over the drain access region 105C and the drain region 105D, a lateral or horizontal segment 116B extending over the source region 105A, as well as a horizontal segment 116C over the gate stack 112, where vertical segments 118A, 118B formed over respective sidewall surfaces of the gate stack 112 extend from the horizontal segment 116C to the horizontal segments 116A, 116B extending over each side of the gate stack 112. Whereas the thicknesses of the horizontal segment 116C and the vertical segments 118A, 118B covering the gate stack 112 may vary depending on the topography of the gate stack 112 and/or underlying material composition, the horizontal segments 116A and 116B of the oxidized layer 119 formed in or over the barrier layer 110 may be about 2 nm to 5 nm or less in some examples herein.

Surface interaction of the plasma species with the barrier layer 110 in forming an oxidized layer on or in the barrier layer 110 may cause changes in the quantum well formed due to the different band gaps of the materials of the heterojunction structure of the GaN device 101. Such changes in the quantum well may contribute to an increase in the carrier density and/or mobility in the 2DEG channel 108 depending on the plasma chemistry configured in a plasma treatment.

Turning to FIG. 1C, a passivation layer 120 is formed over the GaN device 101. In some implementations, the passivation layer 120 may comprise silicon nitride (SiN) layer having a thickness of about 50 nm to 100 nm formed in an LPCVD process.

In FIG. 1D, a cross-sectional view of a more completely formed semiconductor device 100 including the GaN device 101 is illustrated. As depicted, a dielectric layer 122 is formed over the passivation layer 120 of the GaN device 101. In some implementations, the dielectric layer 122 may comprise a PECVD SiN layer having a thickness of about 50 nm to 100 nm. A contact photolithography and etch process may be configured to pattern contact openings in the dielectric layers 122 and 120 over the source region 105A, the gate region 105B and the drain region 105D. A source terminal or contact 125A is formed extending through the dielectric layers 122, 120 and the horizontal segment 116A of the oxidized layer 119, and into the barrier layer 110. In similar manner, a drain terminal or contact 125B is formed extending through the dielectric layers 122, 120 and the horizontal segment 116B of the oxidized layer 119, and into the barrier layer 110. A gate terminal or contact 125C is formed extending through the dielectric layers 122, 120 and the horizontal segment 116C of the oxidized layer 119, and into the AlGaN cap 115 of the gate stack 112. The source contact 125A, the drain contact 125B and the gate contact 125C are electrically conductive, and may include one or more metals, such as titanium, nickel, tungsten, or aluminum, or may include other electrically conductive material such as carbon nanotubes or graphene.

As noted previously, the source terminal 125A and the drain terminal 125B are asymmetrically disposed relative to the gate terminal 125C because of the presence of the drain access region 105C. For purposes of the examples herein, a drain access region may be an area of the device region disposed between a gate terminal and a drain terminal of the device. Likewise, a source access region, where provided, may be an area of the device region disposed between a gate terminal and a source terminal of the device, which may have a different length, e.g., along the X-axis, than the drain access region.

Although not shown in FIG. 1D, one or more field plates may be optionally provided in association with one or more of the device terminals, e.g., the source terminal 125A, the drain terminal 125B and/or the gate terminal 125C, to mitigate the effects of peak electric fields in the channel layer 106 that may be caused in some high voltage applications. Further, the source terminal 125A, the drain terminal 125B and/or the gate terminal 125C, as well as any optional field plates, may extend into an inter-level dielectric (ILD) and/or pre-metal dielectric (PMD) insulator layer 127, and may be covered by a protective overcoat (PO) (not shown in FIG. 1D) of the semiconductor device 100.

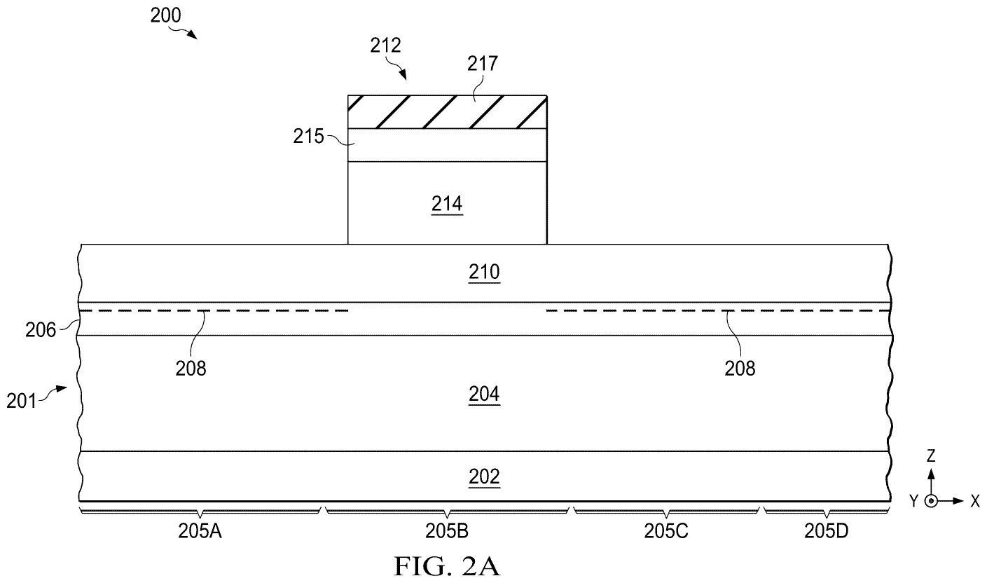

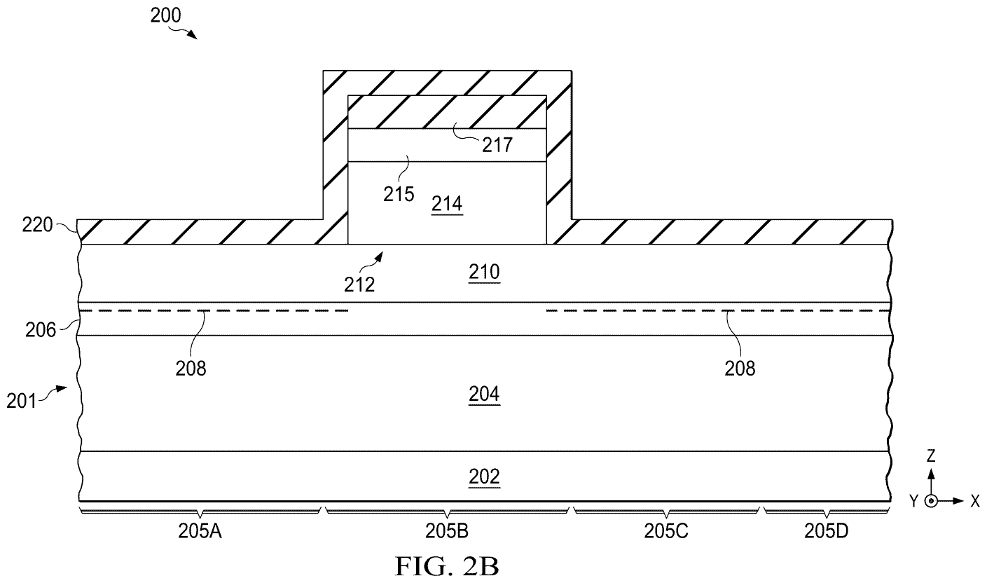

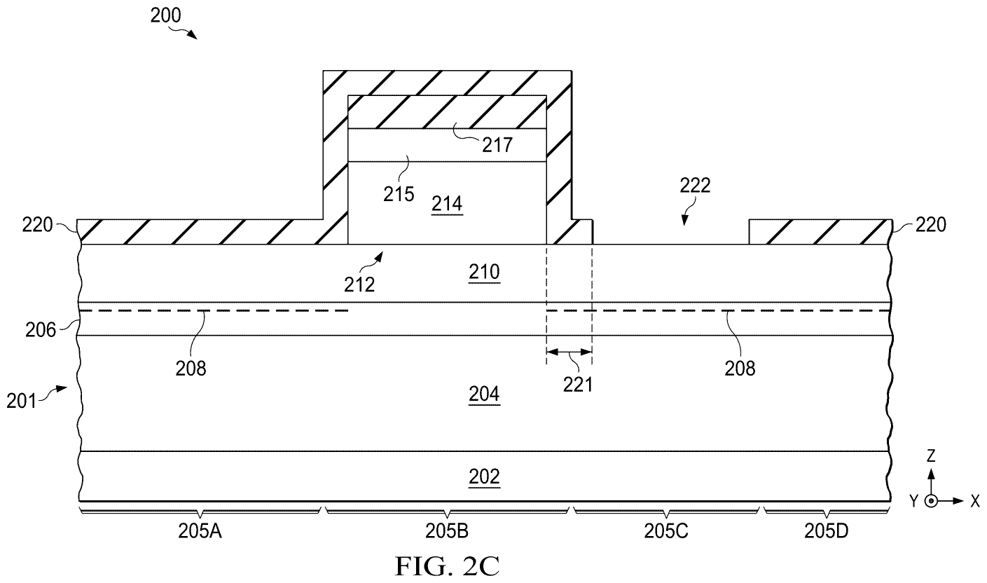

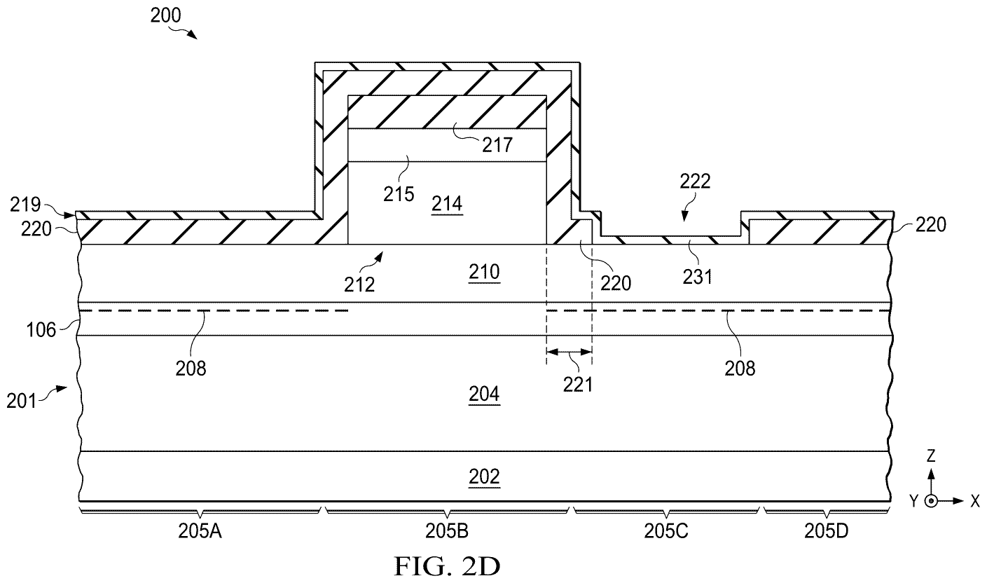

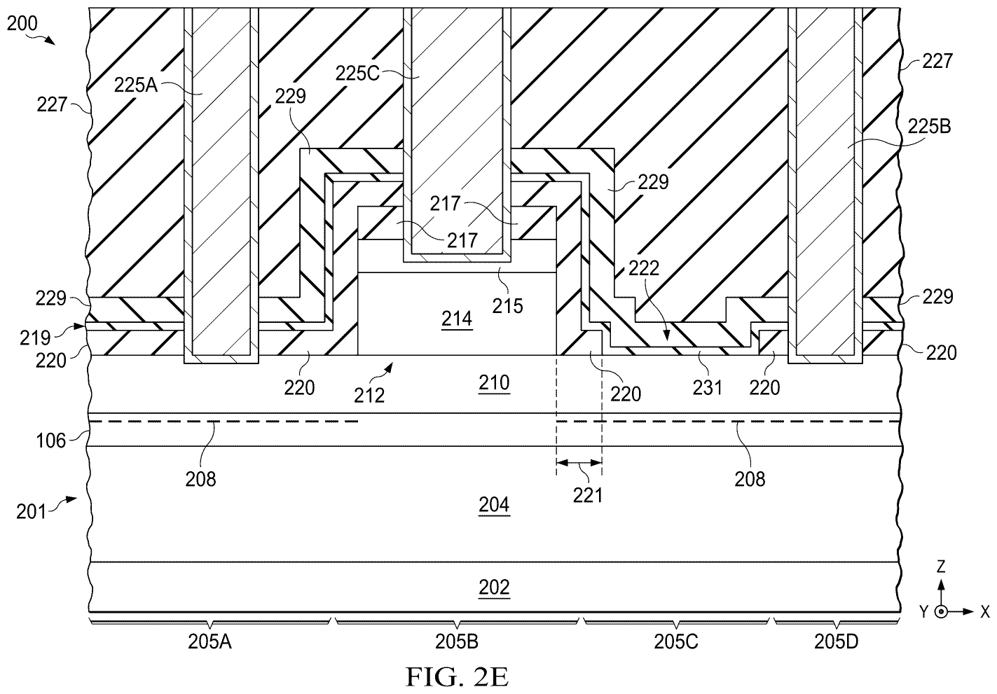

FIGS. 2A-2E depict cross-sectional views of a semiconductor device 200 including an EMODE GaN device 201 at various stages of a process flow, where an oxidized layer is provided in or over a barrier layer only in a portion of a drain access region of the GaN device according to some examples of the present disclosure. The process flow stages of FIGS. 2A-2E are substantially similar to the process flow stages of FIGS. 1A-1D described above except as noted herein with respect to the stage where an oxidized layer is formed. Accordingly, the description relating to the fabrication of the GaN device 101 is equally applicable with respect to the fabrication of the GaN device 201 apart from the modifications necessary to form the oxidized layer only in a portion of the drain access region of the GaN device 201. In the intermediate stage of FIG. 2A, the semiconductor device 200 is identical to the semiconductor device 100 of FIG. 1A and comprises a GaN device 201 including a source region, 205A, a gate region 205B, a drain region 205D and a drain access region 205C between the gate region 205B and the drain region 205D in a substrate 202. Analogous to the example of FIG. 1A, a buffer layer 204, channel layer 206 supporting a 2DEG channel 208, and a barrier layer 210 are formed in the stage shown in FIG. 2A. Likewise, a gate stack 212 is formed over the barrier layer 210 in the gate region 205B of the GaN device 201, where the gate stack 212 includes a p-GaN layer 214, an AlGaN cap 215 and a dielectric cap 217, that may be patterned similar to the gate stack 112 set forth above.

In FIG. 2B, a dielectric layer 220 is formed as a passivation layer over the GaN device 201, which may comprise an LPCVD SiN layer of suitable thickness, e.g., about 50 nm to 100 nm. An opening or aperture having a suitable form factor and dimensions (e.g., having a rectangular shape) may be formed in the dielectric layer 220, e.g., by a pattern etch comprising wet etch and/or dry etch. As illustrated in the cross-sectional view of FIG. 2C, an aperture 222 may be formed in the dielectric layer 220, which may be laterally spaced apart from the gate stack 212 by a distance 221, to expose a corresponding portion of the barrier layer 210 overlying the drain access region 205C. In some examples, the aperture 222 may overlie at least a portion of the drain access region 205C. In some examples, the aperture 222 may extend over only a portion of the drain access region 205C. In some examples, multiple apertures 222 overlying a section of the drain access region 205C may be provided by suitable patterning of the dielectric layer 220.

FIG. 2D depicts a stage where an oxidized layer 219 is formed over the GaN device 201 using a plasma treatment similar to the process set forth in FIG. 1B. Because only a portion of the barrier layer 210 overlying the drain access region 205C is exposed in the aperture 222, the oxidized layer 219 may include a single segment 231 formed in the aperture 222 (or multiple segments if multiple apertures are provided), which may beneficially impact the carrier density and/or mobility in the 2DEG channel 208. Additional oxidized segments formed over the dielectric layer 220 do not have a direct interface with the barrier layer 210 in the remaining regions of the GaN device 201, and therefore may not be effective in modulating the carrier parameters in the 2DEG channel 208.

FIG. 2E depicts a cross-sectional view of a more completely formed semiconductor device 200 including the GaN device 201. Analogous to the semiconductor device 100 illustrated in FIG. 1D, a PECVD dielectric layer 229 is formed over the GaN device 201, which is patterned to form a source contact or terminal 225A, a drain contact or terminal 225B and a gate contact or terminal 225C using similar processes, metallurgies, etc. Likewise, the source terminal 225A, the drain terminal 225B and/or the gate terminal 225C may be provided with any optional field plates, where the terminals and respective field plates may extend into an ILD/PMD layer 227 of the semiconductor device 200.

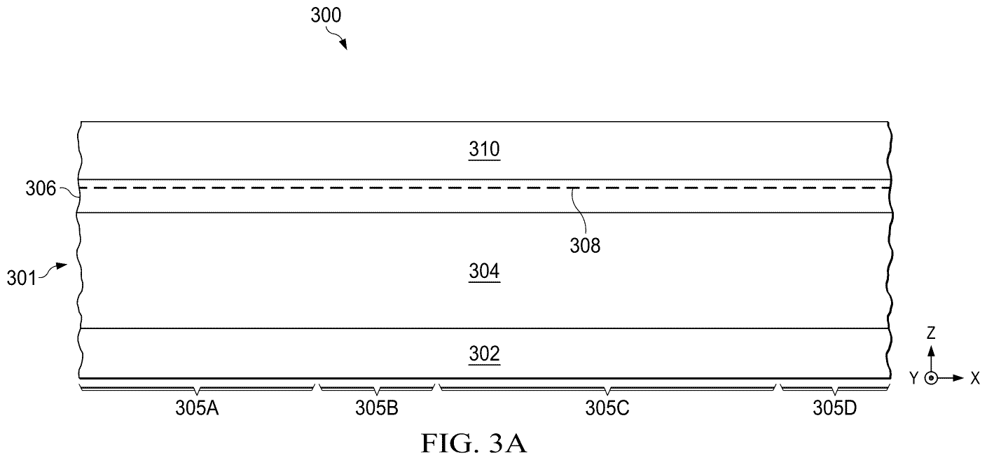

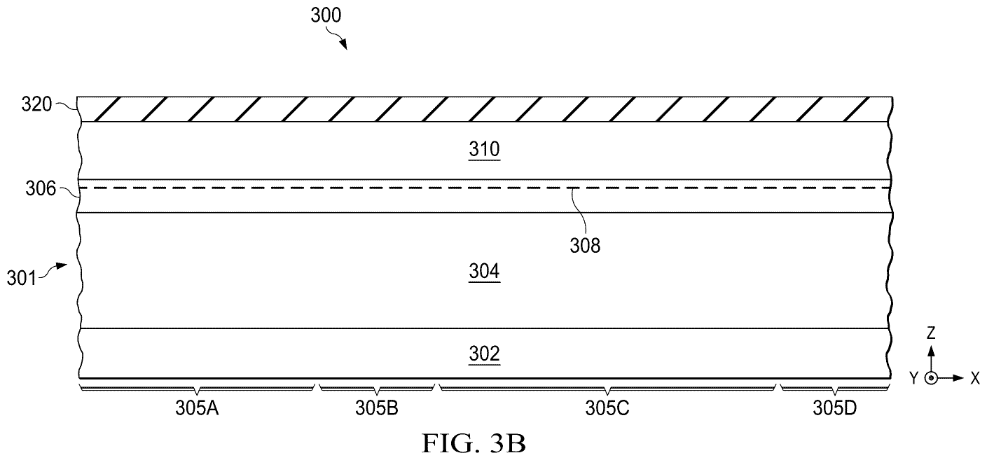

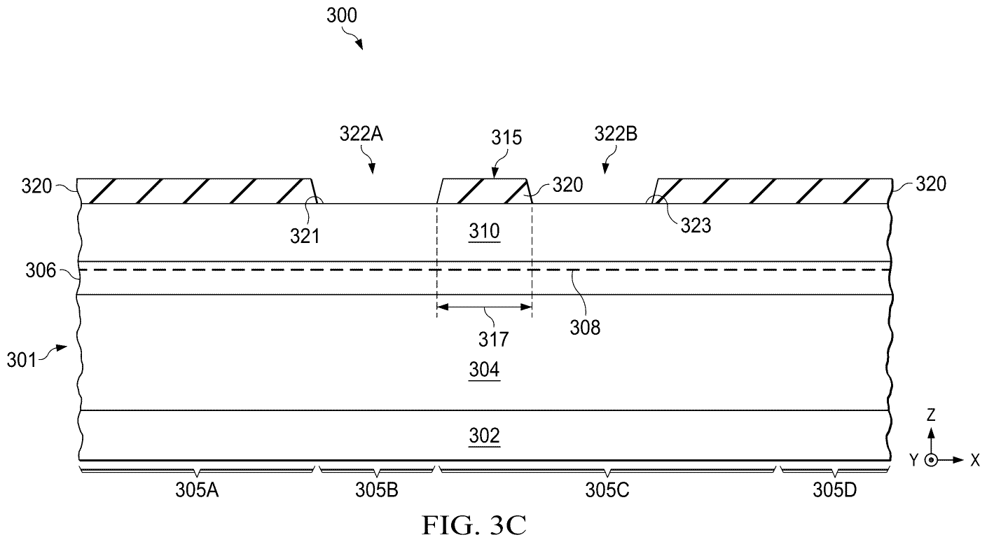

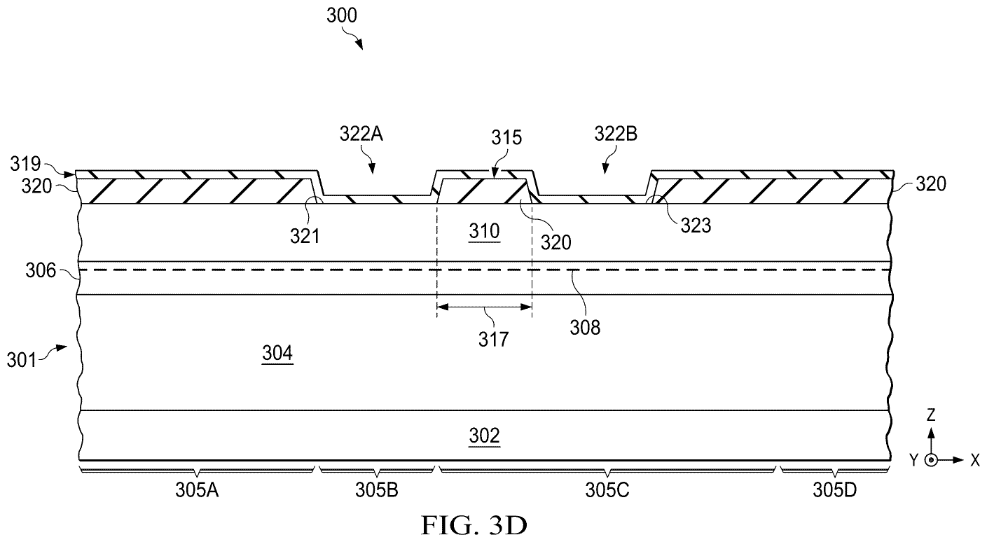

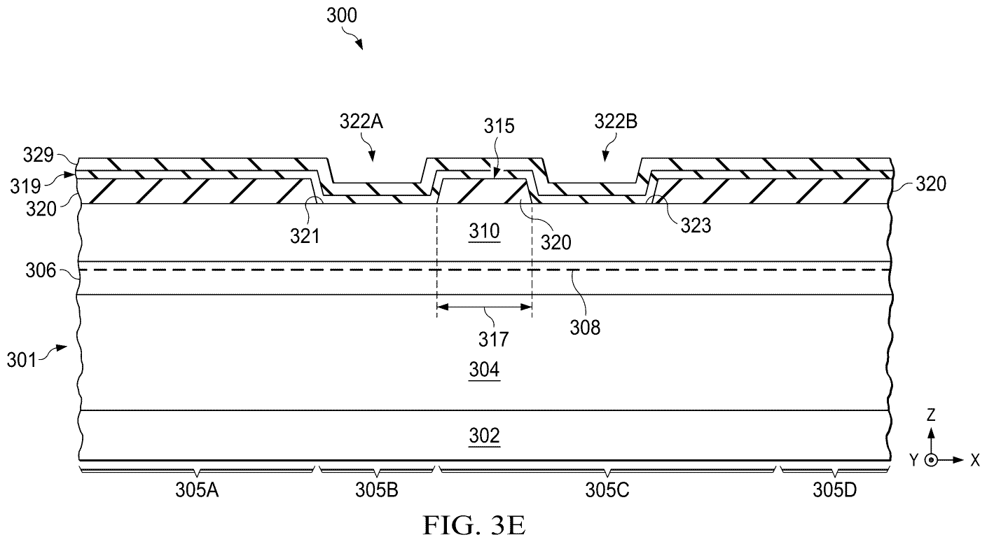

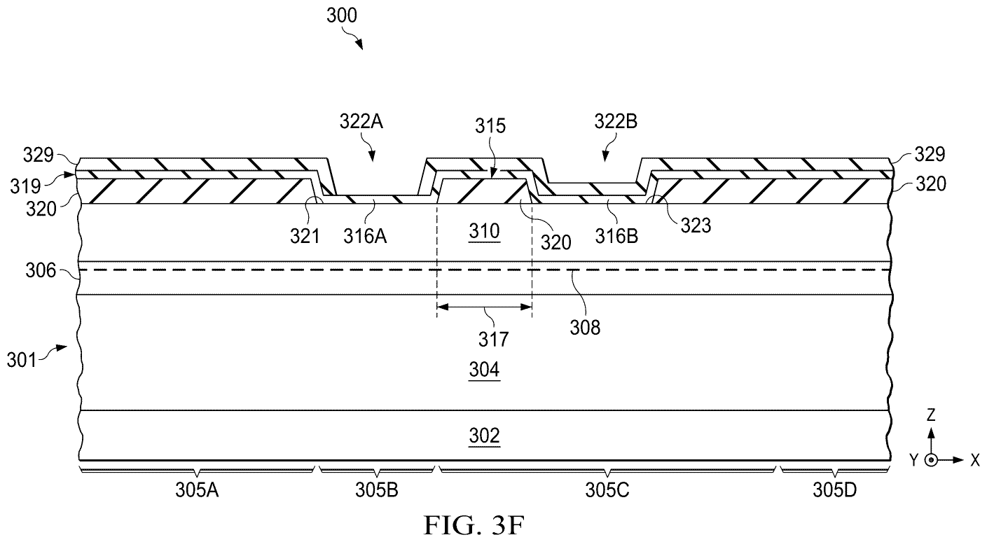

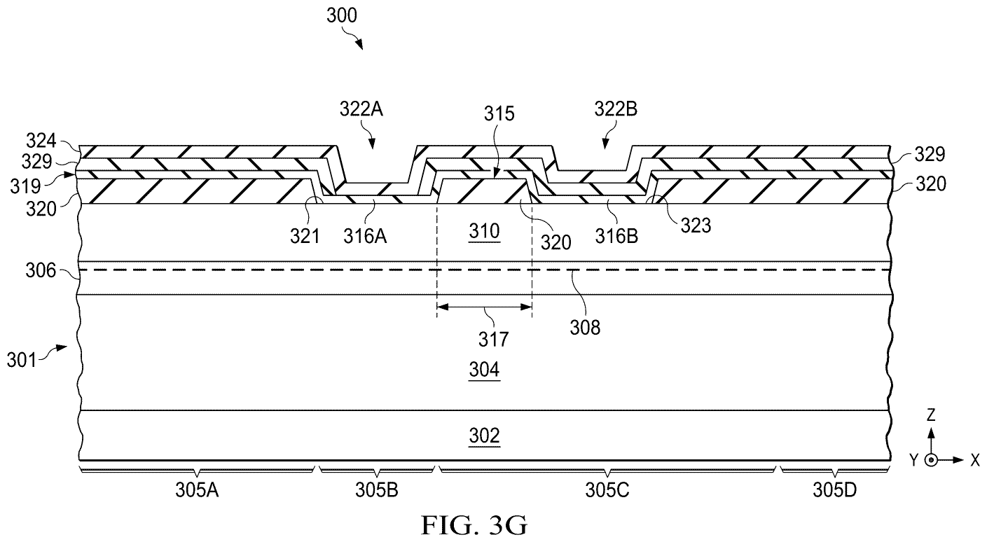

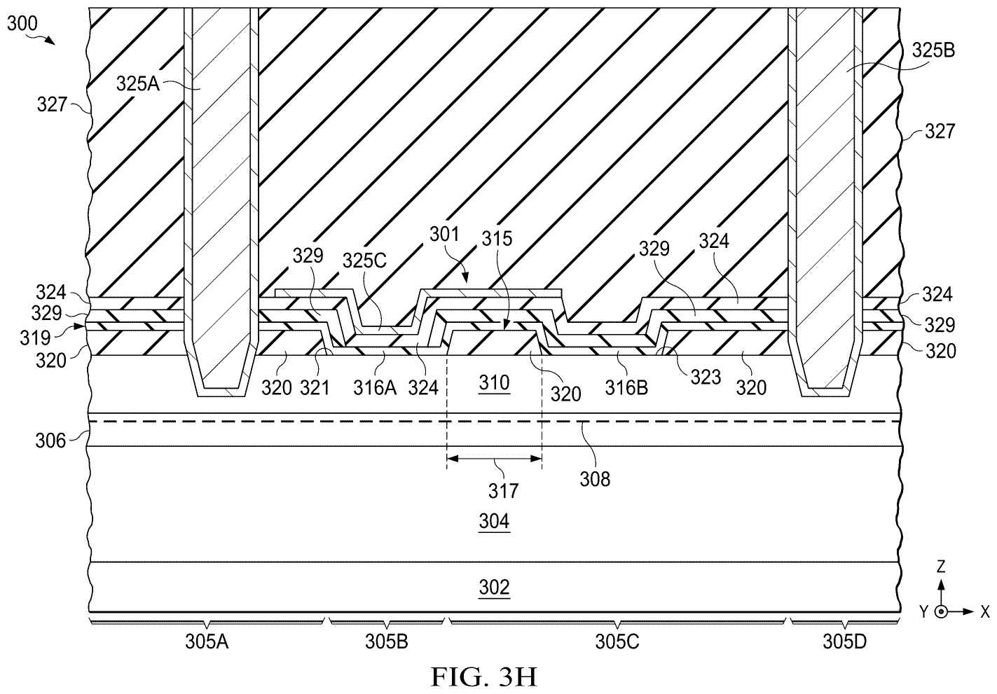

Analogous to the EMODE GaN examples set forth above, additional and/or alternative examples of the present disclosure disclose DMODE GaN examples where an oxidized layer may be formed over a barrier layer in select regions of the DMODE GaN device using a similar plasma treatment in order to enhance the carrier density and/or mobility in a 2DEG channel. FIGS. 3A-3H depict cross-sectional views of a semiconductor device 300 including a DMODE GaN device 301 at various stages of a process flow, where an oxidized layer may be provided in or over a barrier layer in a gate region and/or only in a portion of a drain access region of the GaN device according to some examples of the present disclosure. Apart from the fabrication of a DMODE GaN device, which as a normally on device does not include a p-GaN gate stack in the examples herein, example plasma treatments to form the oxidized layer segments in the barrier layer of the select regions of the DMODE GaN device are similar to the plasma treatment options and process conditions set forth above. Accordingly, the plasma treatment options and associated process conditions applied in the fabrication of EMODE GaN devices are equally applicable to the fabrication of DMODE GaN devices, with appropriate or relevant modifications as will be noted below.

FIG. 3A depicts an intermediate stage of the semiconductor device 300, which includes a suitable substrate 302 and one or more III-N layers operable as a buffer layer 304, a channel layer 306 configured to support a 2DEG channel 308 and a barrier layer 310 with respect to a GaN device 301 to be formed, similar to the semiconductor devices 100, 200 described above. Additional details relevant to the formation of DMODE devices such as the semiconductor device 300, including intermediate stages, may be found in one or more incorporated disclosures, as previously noted.

FIG. 3B depicts a stage where a dielectric layer 320, e.g., an LPCVD SiN layer having a thickness of about 50 nm to 100 nm, is formed as a passivation layer over the barrier layer 310.

FIG. 3C depicts a stage where the dielectric layer 320 is patterned (e.g., using suitable photolithography and etch processes including wet etch and/or dry etch) to form apertures 322A, 322B in select regions of the GaN device 301. As illustrated, aperture 322A is formed over a gate region 305B and aperture 322B is formed over a drain access region 305C disposed between the gate region 305B and a drain region 305D. In the examples herein, the aperture 322A may also be referred to as a gate aperture because a gate dielectric layer and a gate terminal may be formed therein in addition to forming an oxidized layer segment at an interface 321 of the barrier layer 310 during a plasma treatment. In similar fashion, the aperture 322B may be referred to as a drain access aperture where an oxidized layer segment may be formed at an interface 323 of the barrier layer 310 during the plasma treatment. Depending on implementation and applicable gate design rules, the apertures 322A and 322B may have different dimensions and form factors, and may be laterally spaced apart (e.g., along the X-axis) by a suitable distance 317, thus causing a mesa structure 315 to be formed therebetween.

In versions of the examples herein, the drain access aperture 322B may expose only a portion of the barrier layer 310 in the drain access region 305C, which is the device area disposed between the gate region 305A and the drain region 305D as previously noted. Further, although a separate source access region is not shown in the example of FIG. 3C relative to a source region 305A, some additional and/or alternative examples may include a source access region also, which could be patterned to provide openings for forming oxidized layer segments therein in similar fashion.

FIG. 3D depicts a stage where a plasma treatment is applied to the semiconductor device 300 for forming an oxidized layer 319 having a thickness of about 2 nm to 5 nm or less, similar to the formation of the oxidized layers 119, 219 described above.

FIG. 3E depicts a stage where a dielectric layer 329 is formed over the oxidized layer 319. In some examples, the dielectric layer 329 may comprise an LPCVD SiN layer and may have a thickness (e.g., 35 nm to 50 nm) suitable for supporting gate field plate formation as an optional implementation.

FIG. 3F depicts a stage where the dielectric layer 329 is selectively removed from the bottom of the gate aperture 322A, thus exposing an oxidized layer segment 316A overlying the interface 321, by suitable mask patterning and etching (e.g., wet etch and/or dry etch). The patterning and etching process implemented in the stage of FIG. 3F may leave portions of the dielectric layer 329 on the sidewalls of the gate aperture 322A as well as over the remaining segments of the oxidized layer 319, including over the mesa structure 315 and in the drain access aperture 322B (e.g., oxidized layer segment 316B).

FIG. 3G depicts a stage where a dielectric layer 324 is formed over the topography of the GaN device 301, including the gate aperture 322A, the mesa structure 315 and the drain access aperture 322B. In versions of the examples herein, the dielectric layer 324 may have a suitable thickness, e.g., 20 nm to 30 nm, in the gate aperture 322A so as to operate as a gate dielectric layer for the GaN device 301. Further, the dielectric layer 324 extending over the mesa structure 315 in the drain access region 305C and/or over the source region 305A may be configured, in conjunction with the dielectric layer 329, to support (optional) gate field plates in some examples.

FIG. 3H depicts a cross-sectional view of a more completely formed semiconductor device 300 including the GaN device 301. For example, the GaN device 301 includes a gate electrode 325C in the gate aperture 322A of the gate region 305B. The gate electrode 325C extends to a portion of the dielectric layer 324 in the gate aperture 322A operable as the gate dielectric layer. Moreover, a contact pattern and etch process may be configured to form a source contact or terminal 325A in the source region 305A, a drain contact or terminal 325B in the drain region 305D and a gate contact or terminal (not shown) on the gate electrode 325C. As illustrated, the source contact 325A extends through dielectric layers 324, 329, 320 as well as a horizontal segment of the oxidized layer 319 extending over the source region 305, and into the barrier layer 310 of the source region 305A. Likewise, the drain contact 325B extends through dielectric layers 324, 329, 320 as well as a horizontal segment of the oxidized layer 319 extending over the drain region 305D, and into the barrier layer 310 of the drain region 305D. Analogous to the semiconductor devices 100 and 200 described above, the source contact 325A, the drain contact 325B and the gate contact may be formed using similar metallics and/or other electrically conductive material such as carbon nanotubes or graphene. Further, the source terminal 325A, the drain terminal 325B and/or the gate electrode 325C may be provided with optional field plates, where the terminals and respective field plates may extend into an ILD/PMD layer 327 of the semiconductor device 300.

As shown in FIG. 3H, only a portion of the drain access region 305C of the GaN device 301 includes a segment of the oxidized layer 319. Whereas the gate region 305B may also include a segment of the oxidized layer 319, it may be omitted in further examples of the present disclosure depending on the implementation of plasma treatment integration in a fabrication flow.

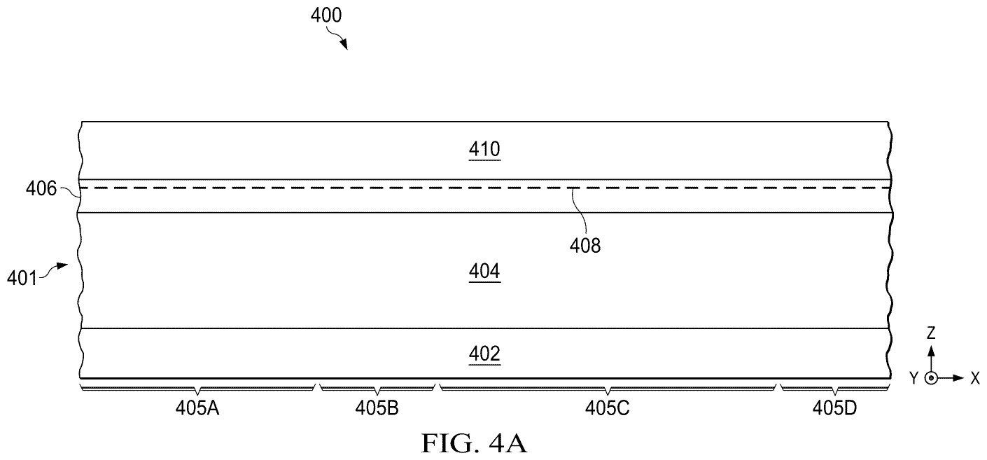

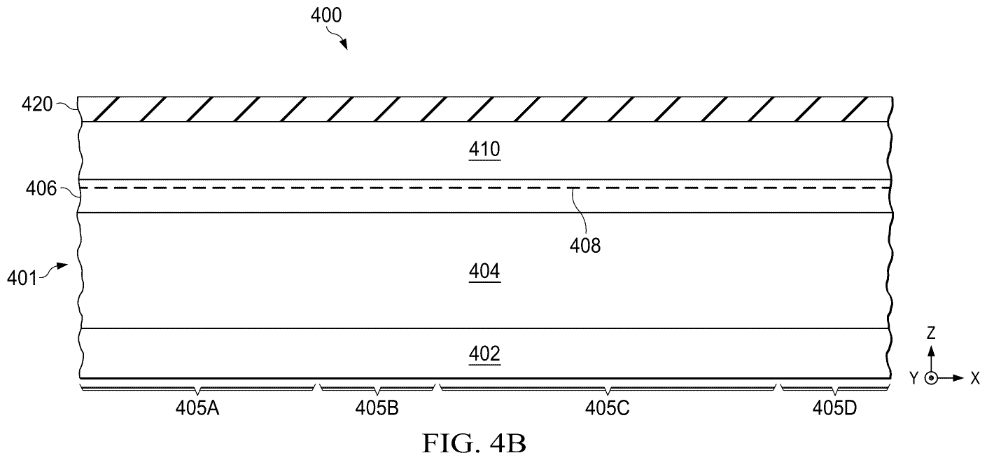

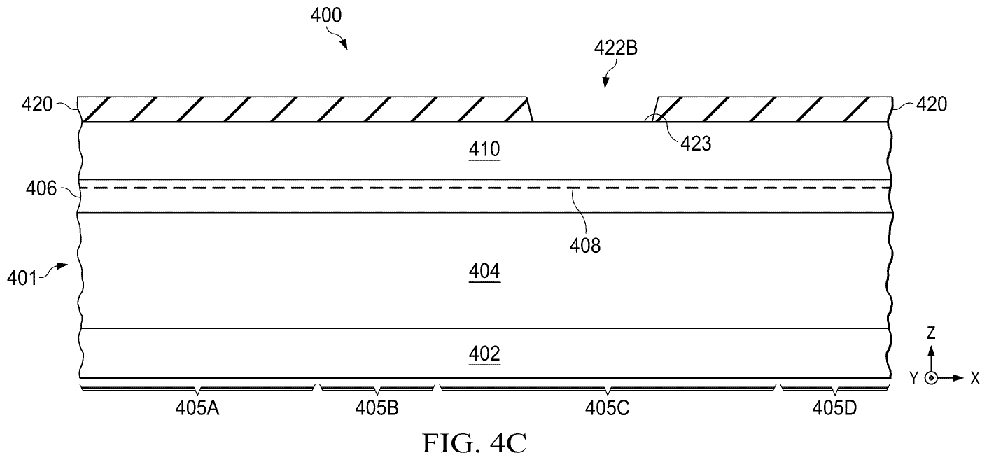

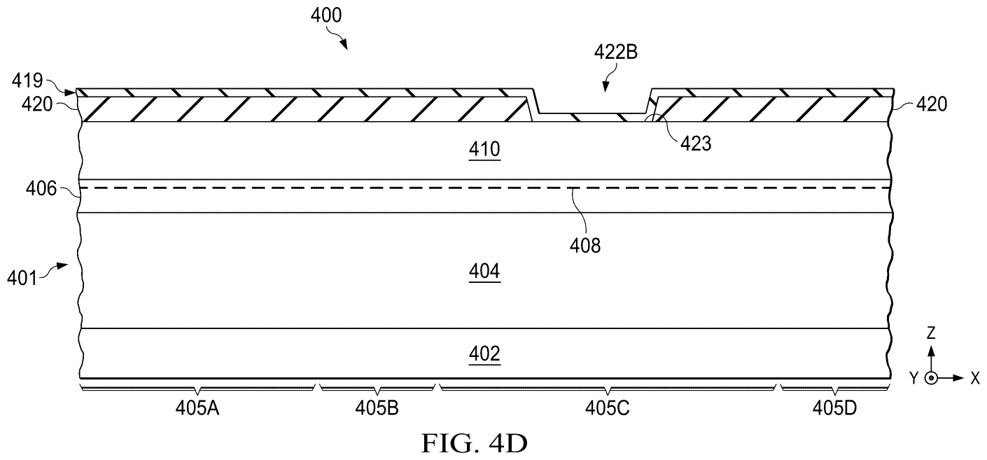

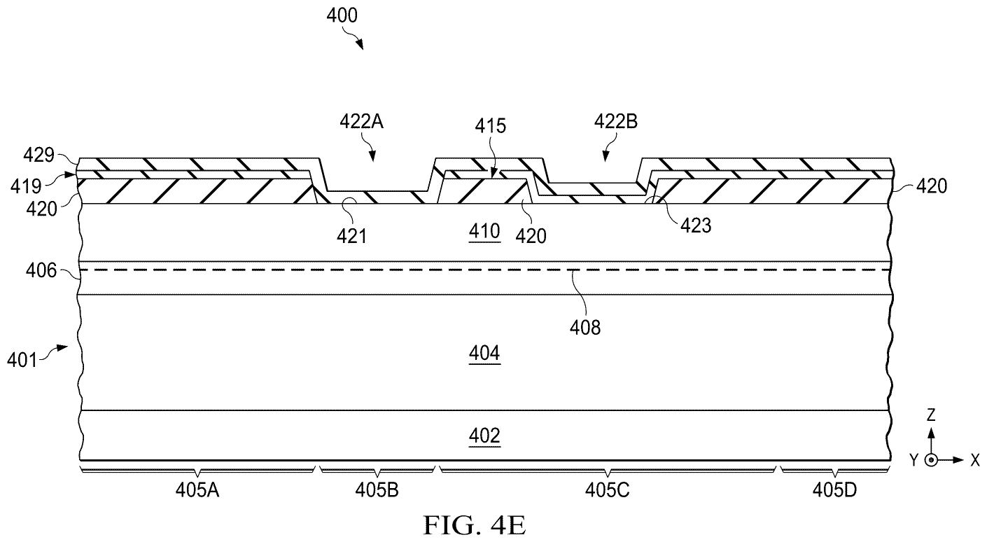

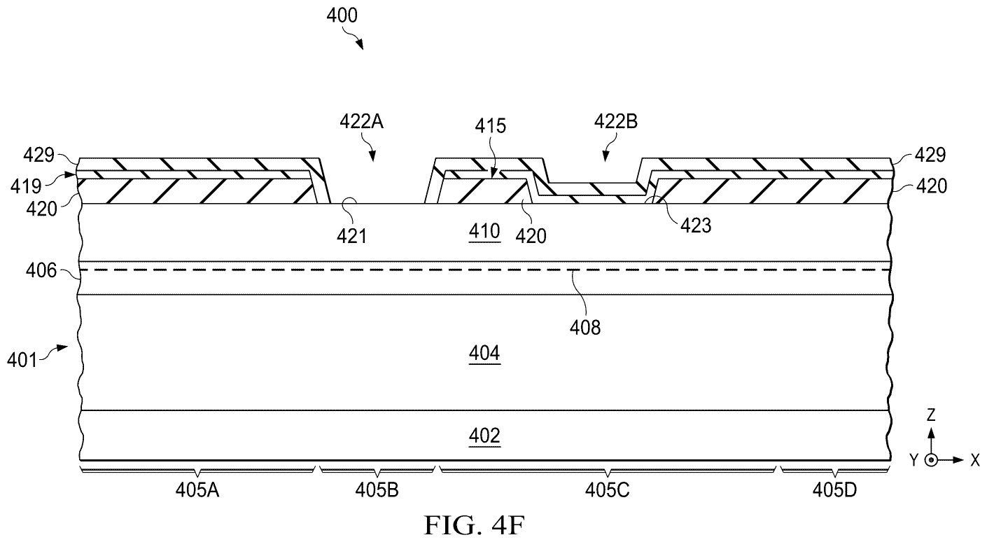

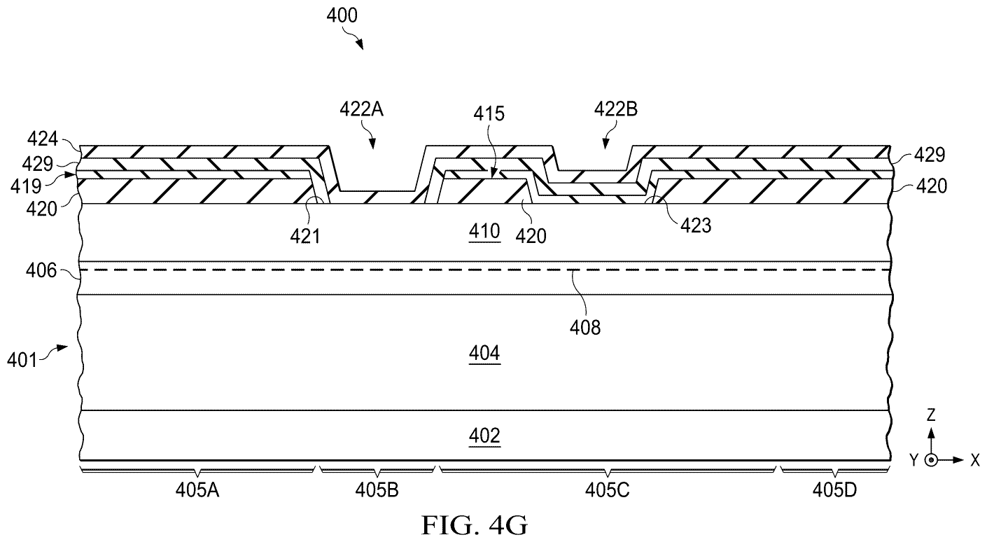

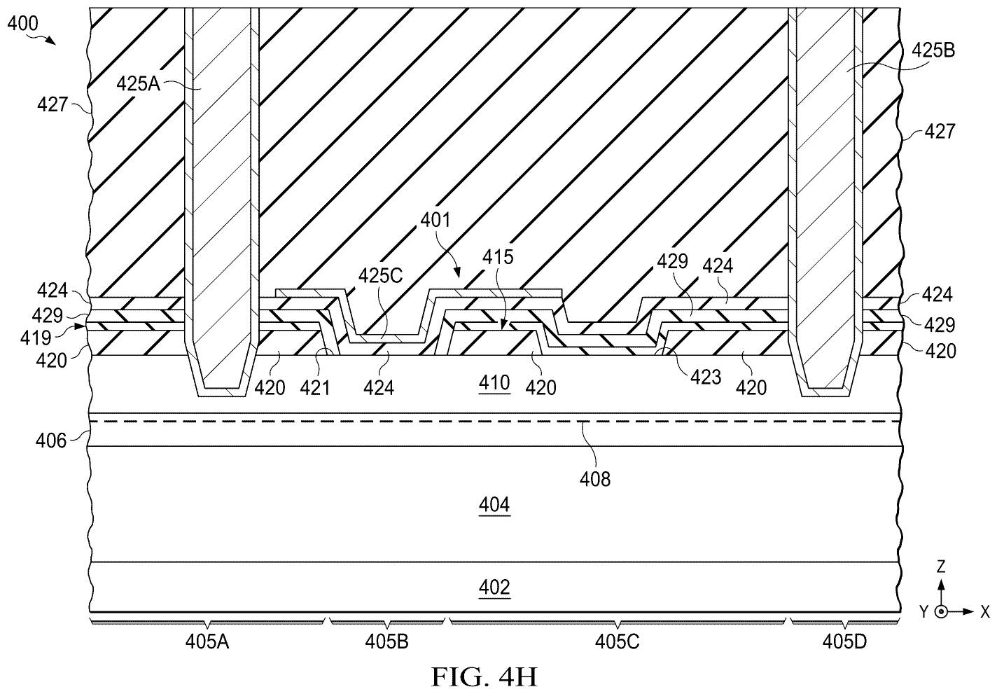

FIGS. 4A-4H depict cross-sectional views of a semiconductor device 400 including a DMODE GaN device 401 at various stages of a process flow, where an oxidized layer may be provided in or over a barrier layer only in a portion of a drain access region of the GaN device 401 according to some examples of the present disclosure. The process flow stages of FIGS. 4A-4H are substantially similar to the process flow stages of FIGS. 3A-3H described above except as noted herein with respect to the stage where an oxidized layer is formed. Whereas two apertures 322A, 322B are formed in a passivation layer, e.g., the dielectric layer 320, overlying the barrier layer 310 in the processing stage of FIG. 3C, with each aperture exposing the barrier layer 310 in respective device regions for forming oxidized layer segments therein, the example of FIG. 4C depict a stage where only one aperture, a drain access aperture 422B, is formed in a dielectric layer 420 overlying a barrier layer 410 in a drain access region 405C.

In general, the description relating to the fabrication of the GaN device 301 is broadly applicable with respect to the fabrication of the GaN device 401 apart from the modifications necessary to form a separate aperture, e.g., a gate aperture 422A shown in FIG. 4E, in a gate region 405B of the GaN device 401. In the intermediate stages of FIGS. 4A and 4B, the semiconductor device 400 is identical to the semiconductor device 300 of FIGS. 3A, 3B, and comprises a GaN device 410 including a source region 405A, a gate region 405B, a drain region 405D, and a drain access region 405C between the gate region 405A and the drain region 405D in a substrate 402. Analogous to the stages of FIGS. 3A and 3B, a buffer layer 404, a channel layer 406 supporting a 2DEG channel 408, and a barrier layer 410 as well as a dielectric layer 420 are formed as shown in the stages of FIGS. 4A and 4B.

In the stage shown in FIG. 4C, a drain access aperture 422B is formed in the dielectric layer 420, exposing an interface 423 of the barrier layer 410 in the drain access region 405C of the GaN device 401. In versions of the examples herein, the drain access aperture 422B is formed in a patterning and etch process similar to the process stage of FIG. 3C, and may extend in only a portion of the entire drain access region 405C.

FIG. 4D depicts a stage where a plasma treatment is applied to the semiconductor device 400 for forming an oxidized layer 419 having a thickness of about 2 nm to 5 nm or less, similar to the formation of the oxidized layers 119, 219, 319 described above. FIG. 4E depicts a stage where a gate aperture 422A is formed through oxidized layer 419 and the dielectric layer 420 in the gate region 405B, which exposes the barrier layer 410 therein, in addition to causing a mesa structure 415 formed in the drain access region 405C. Further, a dielectric layer 429 is formed over the GaN device 401. In versions of the examples herein, the dielectric layer 429 may be formed similar to the process of forming the dielectric layer 329 set forth above, and may be configured to support optional gate field plate formation in some arrangements.

FIG. 4F depicts a stage where the dielectric layer 429 is selectively removed from the bottom of the gate aperture 422A, thus exposing an interface 421 of the barrier layer 410, using suitable mask patterning and etching (e.g., wet etch and/or dry etch). The patterning and etching process implemented in the stage of FIG. 4F may leave portions of the dielectric layer 429 on the sidewalls of the gate aperture 422A as well as over the remaining segments of the oxidized layer 419, including over the mesa structure 415 and in the drain access aperture 422B.

FIG. 4G depicts a stage where a dielectric layer 424 is formed over the topography of the GaN device 401, including the gate aperture 422A, the mesa structure 415 and the drain access aperture 422B. In versions of the examples herein, the dielectric layer 424 may have a suitable thickness, e.g., 20 nm to 30 nm, in the gate aperture so as to operate as a gate dielectric layer for the GaN device 401. The dielectric layer 424 is in direct contact with the barrier layer 410 in the gate aperture 422A. Further, the dielectric layer 424 extending over the mesa structure 415 in the drain access region 405C and/or over the source region 405A may be configured, in conjunction with the dielectric layer 429, to support (optional) gate field plates in some arrangements similar to the example of FIG. 3G.

FIG. 4H depicts a cross-sectional view of a more completely formed semiconductor device 400 including the GaN device 401, which is essentially similar to the GaN device 301 described above except that there is no oxidized layer segment in the gate region 405B. Similar to the GaN device 301, the GaN device 401 includes a gate electrode 425C in the gate aperture 422A of the gate region 405B. The gate electrode 425C extends to a portion of the dielectric layer 424 in the gate aperture 422A operable as the gate dielectric layer in contact with the barrier layer 410. Analogous to the structure shown in FIG. 3H, a contact pattern and etch process may be applied to form a source contact or terminal 425A in the source region 405A, a drain contact or terminal 425B in the drain region 405D and a gate contact or terminal (not shown) on the gate electrode 425C. Further, only a portion of the drain access region 405C of the GaN device 401 includes a segment of the oxidized layer 419, similar to the semiconductor device 300 shown in FIG. 3H.

As illustrated, in FIG. 4H, the source contact 425A extends through dielectric layers 424, 429, 420 as well as a horizontal segment of the oxidized layer 419 extending over the source region 405A, and into the barrier layer 410 of the source region 405A. In similar fashion, the drain contact 425B extends through dielectric layers 424, 429, 420 as well as a horizontal segment of the oxidized layer 419 extending over the drain region 405D, and into the barrier layer 410 of the drain region 405D. Analogous to the semiconductor devices 100, 200, 300 described above, the source contact 425A, the drain contact 425B and the gate contact may be formed using similar metallics and/or other electrically conductive material such as carbon nanotubes or graphene. Additionally and/or alternatively, the source terminal 425A, the drain terminal 425B and/or the gate electrode 425C may be provided with optional field plates, where the terminals and respective field plates may extend into an ILD/PMD layer 427 of the semiconductor device 400. Further, only a portion of the drain access region 405C of the GaN device 401 includes a segment of the oxidized layer 419, similar to the semiconductor device 300 shown in FIG. 3H.

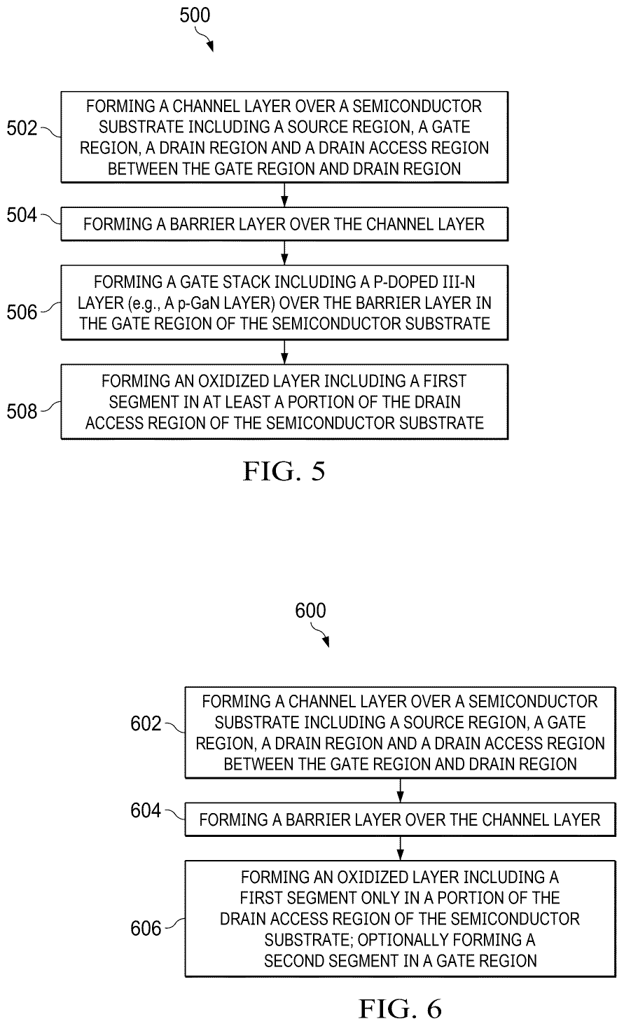

FIGS. 5 and 6 are flowcharts of methods of fabricating a semiconductor device including a GaN device having a segmented oxidized layer in or over a barrier layer according to some examples of the present disclosure. Method 500 of FIG. 5 illustrates a process for providing one or more oxidized layer segments in select device regions of an EMODE device. At block 502, a channel layer may be formed over a semiconductor substrate including a source region, a gate region, a drain region, and a drain access region between the gate region and the drain region. At block 504, a barrier layer may be formed over the channel layer. At block 504, a gate stack including a p-doped III-N (p-III-N or p-GaN) layer may be formed over the barrier layer in the gate region of the semiconductor substrate, where the p-GaN layer may be doped using Mg or other p-type dopants as set forth previously. At block 506, an oxidized layer including a first segment may be formed in at least a portion of the drain access region of the semiconductor substrate. As set forth previously with respect to the process stages shown in FIGS. 1A-1D and FIGS. 2A-2E, some examples may be configured to expose the barrier layer of the GaN device in the entire drain access region or only a portion thereof using a patterned dielectric layer for a plasma treatment based on select chemical species and suitable process conditions.

Method 600 of FIG. 6 illustrates a process for providing one or more oxidized layer segments in select device regions of a DMODE device. Similar to block 502 set forth above, a channel layer may be formed over a semiconductor substrate including a source region, a gate region, a drain region, and a drain access region between the gate region and the drain region (block 602). Thereafter, a suitable barrier layer may be formed over the channel layer (block 604). In one arrangement, an oxidized layer including a segment (e.g., a first segment) only in a portion of the drain access region of the semiconductor substrate may be formed (block 606). In another and/or alternative arrangement, a second oxidized layer segment may also be formed in a gate region of the semiconductor device. As set forth previously with respect to the process stages shown in FIGS. 3A-3H and FIGS. 4A-4H, some examples may be configured to expose the barrier layer of the GaN device only in a portion using a patterned dielectric layer for a plasma treatment based on select chemical species and suitable process conditions similar to the acts and operations set forth at block 506.

In some examples, the plasma treatment for oxidizing select portions of a barrier layer may be based on N₂O chemistry as previously noted. Favorable results have been observed in electron gas density as well as carrier mobility in 2DEG channels of example GaN devices in addition to concomitant benefits in several related electrical parameters such as on-resistance, channel sheet resistance, contact resistance, etc. By way of example only, electron gas density in drain access regions of the example devices has been observed to be about 25% higher in some implementations. As a further example, channel sheet resistance of the example devices has been observed to be about 25% lower in some implementations.

In additional and/or alternative arrangements, a plasma treatment based on oxygen (O₂) chemistry may be implemented according to some examples herein where a barrier layer may be selectively exposed in certain regions of the device similar to the examples described in detail hereinabove. Depending on implementation, oxygen may be supplied to the reactor chamber of a PECVD tool at a flow rate of about 1.5 slm to 2.5 slm for about 60 to 90 seconds. In versions of this arrangement, both RF power and low frequency (LF) power may be applied, e.g., with RF power of about 500 W to 600 W and having a frequency range of about 10 MHz to 20 MHz as well as LF power of about 300 W and having a frequency range of about 300 kHz to 500 kHz. Further, a chamber pressure of about 300 Pa to 400 Pa and a temperature of about 350° C. to 450° C. may be maintained during the treatment process similar to the N₂O-based treatments in some arrangements.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately over the other component, or that one component is immediately under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate including a source region, a gate region, a drain region, and a drain access region between the gate region and the drain region;
a channel layer over the semiconductor substrate;
a barrier layer over the channel layer;
a gate stack including a p-doped III-N layer over the barrier layer in the gate region; and
an oxidized layer including a first segment in at least a portion of the drain access region.

2. The semiconductor device as recited in claim 1, wherein the oxidized layer includes a second segment in at least one of the source region and the drain region.

3. The semiconductor device as recited in claim 2, wherein the oxidized layer includes a horizontal segment covering at least a portion of a top surface of the gate stack and one or more vertical segments covering respective sidewalls of the gate stack.

4. The semiconductor device as recited in claim 3, further including:
a source terminal extending through a first instance of the second segment and into the barrier layer;
a drain terminal extending through a second instance of the second segment and into the barrier layer; and
a gate terminal extending through the horizontal segment and into a cap layer of the gate stack.

5. The semiconductor device as recited in claim 2, further including:
a dielectric layer formed over the gate stack, wherein the oxidized layer includes a horizontal segment over the dielectric layer and one or more vertical segments covering respective sidewalls of the dielectric layer formed on vertical surfaces of the gate stack.

6. The semiconductor device as recited in claim 5, where a first instance of the second segment is over a first lateral portion of the dielectric layer extending over the source region and a second instance of the second segment is over a second lateral portion of the dielectric layer extending over the drain access region and the drain region, the semiconductor device further including:
a source terminal extending through the first instance of the second segment, the first lateral portion of the dielectric layer and into the barrier layer;
a drain terminal extending through the second instance of the second segment, the second lateral portion and into the barrier layer; and
a gate terminal extending through the horizontal segment, the dielectric layer over the gate stack and into a cap layer of the gate stack.

7. The semiconductor device as recited in claim 1, wherein the oxidized layer is formed in or over a top surface of the barrier layer.

8. The semiconductor device as recited in claim 1, wherein the oxidized layer has a thickness of about 2 to 3 nanometers (nm) or less.

9. A semiconductor device, comprising:
a semiconductor substrate including a source region, a gate region, a drain region, and a drain access region between the gate region and the drain region;
a channel layer over the semiconductor substrate;
a barrier layer over the channel layer; and
an oxidized layer including a first segment only in a portion of the drain access region.

10. The semiconductor device as recited in claim 9, wherein the oxidized layer includes:
a first horizontal segment over a dielectric layer over the barrier layer in the source region; and
a second horizontal segment over the dielectric layer over the barrier layer in the drain region.

11. The semiconductor device as recited in claim 10, wherein the oxidized layer further includes a third horizontal segment over the dielectric layer over the barrier layer in the gate region, the semiconductor device further comprising:
a source terminal extending through the first horizontal segment, the dielectric layer and into the barrier layer;
a drain terminal extending through the second horizontal segment, the dielectric layer and into the barrier layer; and
a gate terminal extending through the third horizontal segment and into a gate dielectric layer formed in a trench over the barrier layer in the gate region, the gate dielectric layer in contact with the barrier layer.

12. The semiconductor device as recited in claim 10, wherein the oxidized layer further includes a second segment in a trench over the barrier layer in the gate region, the second segment in contact with the barrier layer and the semiconductor device further comprising:
a source terminal extending through the first horizontal segment, the dielectric layer and into the barrier layer;
a drain terminal extending through the second horizontal segment, the dielectric layer and into the barrier layer; and
a gate terminal extending into a gate dielectric layer formed over the second segment in the trench.

13. The semiconductor device as recited in claim 9, wherein the oxidized layer is formed in or over a top surface of the barrier layer.

14. The semiconductor device as recited in claim 9, wherein the oxidized layer has a thickness of about 2 to 3 nanometers (nm) or less.

15. A method, comprising:
forming a channel layer over a semiconductor substrate including a source region, a gate region, a drain region, and a drain access region between the gate region and the drain region;
forming a barrier layer over the channel layer;
forming a gate stack over the barrier layer in the gate region of the semiconductor substrate, the gate stack including a p-doped III-N layer; and
forming an oxidized layer including a first segment in at least a portion of the drain access region of the semiconductor substrate.

16. The method as recited in claim 15, wherein the step of forming the oxidized layer includes forming a second segment in at least one of the source region and the drain region.

17. The method as recited in claim 15, wherein the oxidized layer is formed in or over a top surface of the barrier layer using nitrous oxide in a plasma treatment with a RF power greater than 600 W and at a frequency range of about 10 MHz to 20 MHz.

18. The method as recited in claim 15, wherein the oxidized layer has a thickness of about 2 to 3 nanometers (nm) or less.

19. A method, comprising:
forming a channel layer over a semiconductor substrate including a source region, a gate region, a drain region, and a drain access region between the gate region and the drain region;
forming a barrier layer over the channel layer; and
forming an oxidized layer including a first segment only in a portion of the drain access region.

20. The method as recited in claim 19, wherein the step of forming the oxidized layer includes forming a second segment of the oxidized layer in the gate region.

21. The method as recited in claim 19, wherein the oxidized layer is formed in or over a top surface of the barrier layer using nitrous oxide in a plasma treatment with a RF power greater than 600 W and at a frequency range of about 10 MHz to 20 MHz.

22. The method as recited in claim 19, wherein the oxidized layer has a thickness of about 2 to 3 nanometers (nm) or less.
